(19) United States
(12) Patent Application Publication
(10) Pub. No.: US 2025/0380518 A1
(43) Pub. Date: Dec. 11, 2025

(54) IMAGING DEVICE

(71) Applicant: Sharp Display Technology Corporation, Kameyama City (JP)

(72) Inventor: Hiroyuki MORIWAKI, Kameyama City (JP)

(21) Appl. No.: 19/206,278

(22) Filed: May 13, 2025

(30) Foreign Application Priority Data
Jun. 10, 2024 (JP) 2024-093648

(51) Int. Cl. H10F 39/00; H10F 39/18

(52) U.S. Cl. CPC H10F 39/80373; H10F 39/189; H10F 39/811

(57) ABSTRACT

An imaging device includes an imaging element, a first circuit element disposed on a lower layer side of the imaging element, a first insulating film disposed on an upper layer side of the imaging element, a second insulating film disposed on the upper layer side of the first insulating film, and a third insulating film disposed on the upper layer side of the second insulating film. The first insulating film and the third insulating film each include an inorganic insulating material. The second insulating film includes an organic insulating material and is provided with a first opening overlapping a portion of the first circuit element. The third insulating film includes a first covering portion covering an opening edge of the first opening in the second insulating film.

### CROSS-REFERENCE TO RELATED APPLICATIONS

This application claims the benefit of priority to Japanese Patent Application Number 2024-093648 filed on Jun. 10, 2024. The entire contents of the above-identified application are hereby incorporated by reference.

### BACKGROUND

### Technical Field

The technique disclosed in the present specification relates to an imaging device in which moisture or the like is less likely to diffuse into a second insulating film.

In related art, an imaging device described in JP 2004-179645 A is known as an example of an imaging device. In the imaging device described in JP 2004-179645 A, a plurality of pixels are two-dimensionally arrayed on a substrate. In each of the plurality of pixels, a semiconductor conversion element that converts incident electromagnetic waves into electric signals is paired up with a switching element connected to the semiconductor conversion element. The imaging device includes drive wiring lines each commonly connected to a plurality of the switching elements arrayed in one direction, and signal wiring lines each commonly connected to a plurality of the switching elements arrayed in a direction different from the one direction. The switching element includes a first semiconductor layer. The semiconductor conversion element includes a second semiconductor layer formed after the formation of the switching element and the formation of the first semiconductor layer. An electrode of the semiconductor conversion element is formed in a region in which any two of the drive wiring line, an electrode of the switching element, and the signal wiring line do not overlap each other, except for at least a portion of the drive wiring line and at least a portion of the electrode of the switching element.

### SUMMARY

In JP 2004-179645 A, a protective layer, which is made of SiN and an organic film, is formed after forming openings in a lower electrode that is an electrode of a photodiode serving as the semiconductor conversion element, an n-type semiconductor layer, a second semiconductor layer, and a p-type semiconductor layer. Thereafter, an electrical inspection is performed, and if necessary, a defective portion is subjected to laser repair. At the time of laser repair, a film defect caused by irradiation of laser light may occur in the protective layer. Because of this, there is a concern that moisture or the like may diffuse into the protective layer from the defective portion. If the moisture or the like diffuses into the protective layer, characteristics of the photodiode may deteriorate due to the moisture or the like.

The technique described in the present specification is made based on the above-described circumstances, and an object thereof is to make moisture or the like less likely to diffuse into a second insulating film.

(1) An imaging device relating to a technique described in the present specification includes an imaging element, a first circuit element disposed on a lower layer side of the imaging element, a first insulating film disposed on an upper layer side of the imaging element, a second insulating film disposed on the upper layer side of the first insulating film, and a third insulating film disposed on the upper layer side of the second insulating film. The first insulating film and the third insulating film each include an inorganic insulating material, the second insulating film includes an organic insulating material and is provided with a first opening overlapping a portion of the first circuit element, and the third insulating film includes a first covering portion covering an opening edge of the first opening in the second insulating film.

(2) In addition to (1) above, the imaging device described above may include a second circuit element disposed on the upper layer side of the third insulating film, and a fourth insulating film disposed on the upper layer side of the second circuit element. The fourth insulating film may include an inorganic insulating material and include a second covering portion covering the first covering portion.

(3) In addition to (1) or (2) above, the imaging device described above may include a fifth insulating film disposed on the upper layer side of the third insulating film. The fifth insulating film may include an organic insulating material and include a first filling portion filled in the first opening.

(4) In the imaging device described above, in addition to any one of (1) to (3) above, the first insulating film and the third insulating film may each include silicon nitride as the inorganic insulating material.

(5) In addition to any one of (1) to (4) above, the imaging device described above may include a switching element disposed on the lower layer side of the imaging element, and a sixth insulating film disposed on the upper layer side of the switching element and on the lower layer side of the imaging element. The switching element may include the first circuit element or may be connected to the first circuit element. The sixth insulating film may include an organic insulating material and include a second opening overlapping the first opening. The third insulating film may include a third covering portion covering an opening edge of the second opening in the sixth insulating film.

(6) In the imaging device described above, in addition to (5) above, the first insulating film may include a fourth covering portion covering the opening edge of the second opening in the sixth insulating film, and the third covering portion may cover the fourth covering portion.

(7) In addition to (5) or (6) above, the imaging device described above may include a second circuit element disposed on the upper layer side of the third insulating film, and a fourth insulating film disposed on the upper layer side of the second circuit element. The fourth insulating film may include an inorganic insulating material and include a fifth covering portion covering the third covering portion.

(8) In addition to any one of (5) to (7) above, the imaging device described above may include a seventh insulating film disposed on the upper layer side of the sixth insulating film. The seventh insulating film may include an inorganic insulating material and include a sixth covering portion covering the opening edge of the second opening in the sixth insulating film.

(9) In addition to any one of (5) to (8) above, the imaging device described above may include a fifth insulating film disposed on the upper layer side of the third insulating film. The fifth insulating film may include an organic insulating material and include a first filling portion filled in the first opening and a second filling portion filled in the second opening.

(10) In addition to any one of (1) to (9) above, the imaging device described above may include a switching element disposed on the lower layer side of the imaging element. The switching element may include a gate electrode, a semiconductor portion spaced apart from and overlapping the gate electrode, a source electrode connected to the semiconductor portion, and a drain electrode connected to the semiconductor portion at a position spaced apart from the source electrode. The imaging element may not overlap at least a portion of the source electrode, and may overlap the gate electrode, the semiconductor portion, and the drain electrode. The first circuit element may be the source electrode.

According to the technique described in the present specification, it is possible to make moisture or the like less likely to diffuse into the second insulating film.

### BRIEF DESCRIPTION OF DRAWINGS

The disclosure will be described with reference to the accompanying drawings, wherein like numbers reference like elements.

FIG. 1 is a block diagram illustrating a schematic configuration of a radiographic image capturing system according to a first embodiment.

FIG. 2 is a diagram illustrating a schematic configuration of an imaging device included in the radiographic image capturing system according to the first embodiment.

FIG. 3 is a plan view illustrating a pixel of a substrate included in the imaging device according to the first embodiment.

FIG. 4 is a cross-sectional view of the substrate according to the first embodiment, taken along a line iv-iv in FIG. 3.

FIG. 5 is a cross-sectional view of the substrate according to the first embodiment, taken along a line v-v in FIG. 3.

FIG. 6 is a cross-sectional view of the substrate according to the first embodiment, taken along a line vi-vi in FIG. 3.

FIG. 7 is a cross-sectional view of the substrate according to the first embodiment, taken along a line vii-vii in FIG. 3.

FIG. 8 is a cross-sectional view of a substrate according to a second embodiment, taken along the same cross section as that of FIG. 4.

FIG. 9 is a cross-sectional view of the substrate according to the second embodiment, taken along the same cross section as that of FIG. 7.

FIG. 10 is a plan view illustrating a substrate according to a third embodiment.

FIG. 11 is a cross-sectional view of the substrate according to the third embodiment, taken along a line xi-xi in FIG. 10.

FIG. 12 is a cross-sectional view of the substrate according to the third embodiment, taken along a line xii-xii in FIG. 10.

FIG. 13 is a cross-sectional view of the substrate according to the third embodiment, taken along a line xiii-xiii in FIG. 10.

FIG. 14 is a cross-sectional view of the substrate according to the third embodiment, taken along a line xiv-xiv in FIG. 10.

### DESCRIPTION OF EMBODIMENTS

### First Embodiment

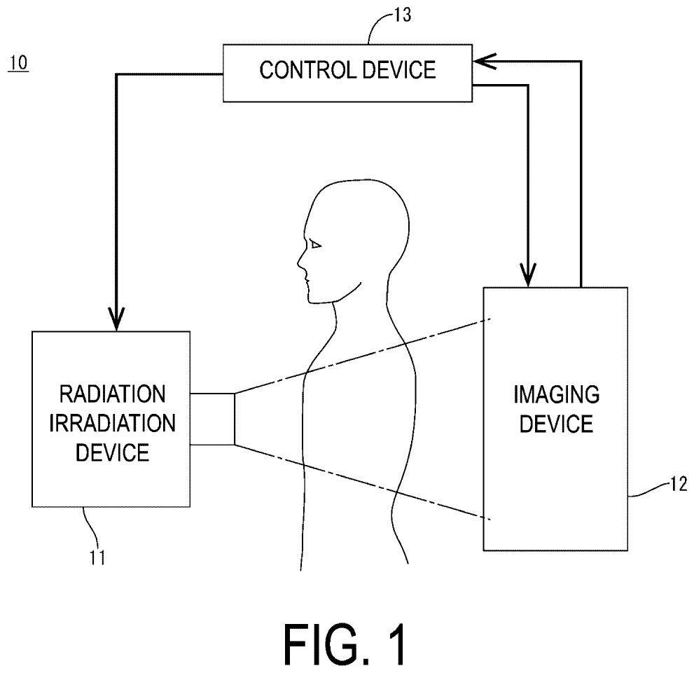

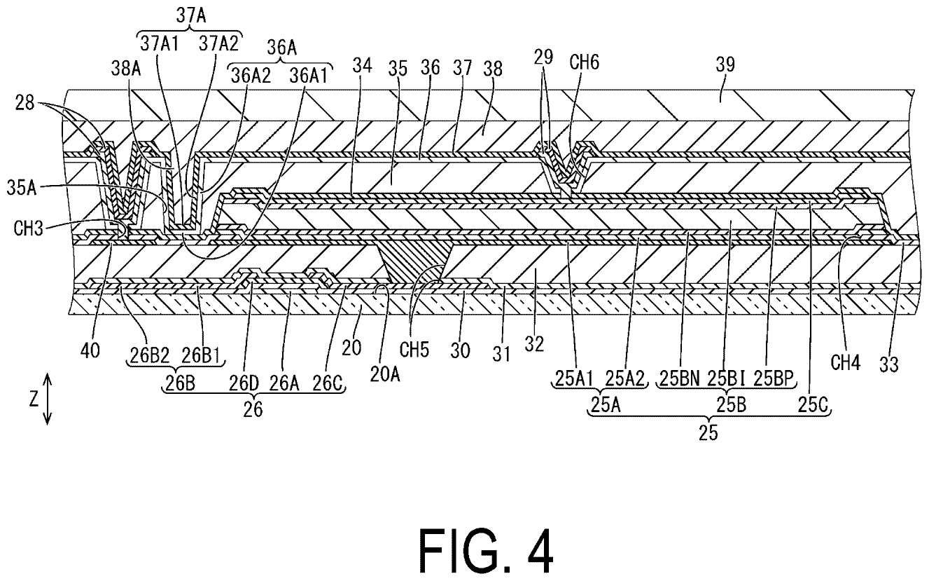

A first embodiment will be described with reference to FIG. 1 to FIG. 7. In the first embodiment, an imaging device 12 included in a radiographic image capturing system 10 is illustrated as an example. Note that some drawings illustrate an X-axis, a Y-axis, and a Z-axis, and directions of these axes are drawn so as to be common in all the drawings. Further, a vertical direction is based on the vertical direction of FIGS. 4 to 7, an upper side of the same drawings is referred to as a front side, and a lower side of the same drawings is referred to as a back side.

As illustrated in FIG. 1, the radiographic image capturing system 10 includes a radiation irradiation device 11 that irradiates a subject (e.g., a human) 1 with radiation (e.g., X rays), the imaging device 12 that captures a radiographic image (image) by detecting the radiation irradiated from the radiation irradiation device 11 and then transmitted through the subject 1, and a control device 13 that controls the radiation irradiation device 11 and the imaging device 12. The radiation irradiation device 11 irradiates the subject 1 with radiation at a timing controlled by the control device 13. The radiation irradiated onto the subject 1 transmits through the subject 1, and as a result, is irradiated onto the imaging device 12 while carrying image information. The imaging device 12 detects the irradiated radiation at a timing controlled by the control device 13, and generates a radiographic image based on the image information carried by the radiation. The radiographic image generated by the imaging device 12 is acquired by the control device 13.

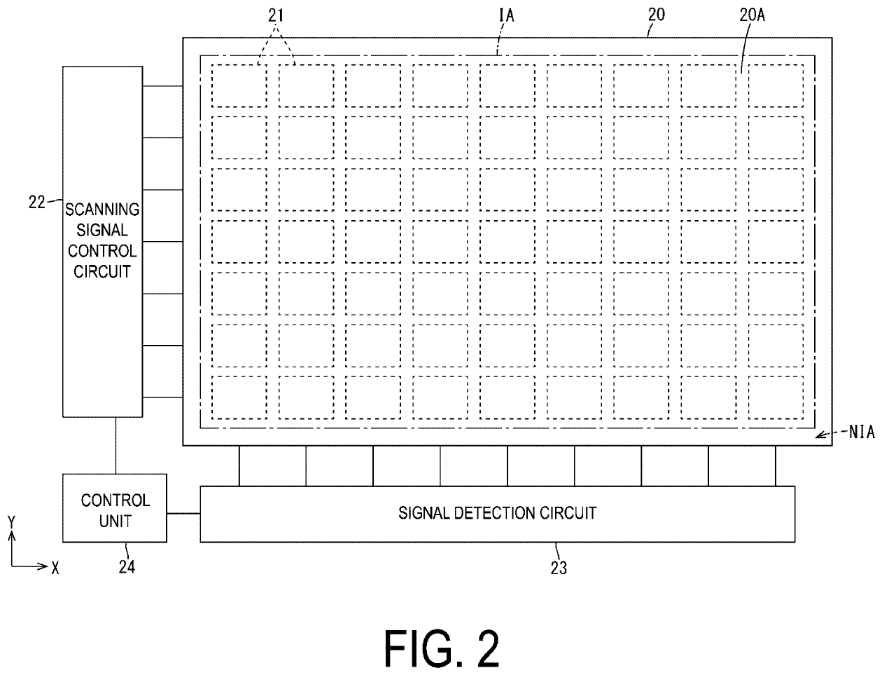

Next, the imaging device 12 will be described in detail. As illustrated in FIG. 2, the imaging device 12 includes a substrate 20 including a plurality of pixels 21, a scanning signal control circuit 22 connected to the substrate 20, a signal detection circuit (signal detection unit) 23 connected to the substrate 20, and a control unit 24 connected to the scanning signal control circuit 22 and the signal detection circuit 23. The substrate 20 includes a main surface 20A that is divided into an imaging region IA in which the plurality of pixels 21 are arrayed and the radiographic image is captured, and a non-imaging region NIA outside the imaging region IA. The substrate 20 is made of a glass material or the like, and transmits light. The pixels 21 are arrayed side by side along the X-axis direction and the Y-axis direction in the imaging region IA, so as to form a matrix shape. The scanning signal control circuit 22, the signal detection circuit 23, and the control unit 24 are provided on a circuit substrate present outside the substrate 20. A flexible substrate is connected to the non-imaging region NIA of the substrate 20 and to the circuit substrate. Therefore, the scanning signal control circuit 22 and the signal detection circuit 23 provided on the circuit substrate are connected to the substrate 20 via the flexible substrate. A terminal connected to a terminal on the flexible substrate side is provided at a portion, of the non-imaging region NIA of the substrate 20, connected to the flexible substrate. The scanning signal control circuit 22 can output a scanning signal for driving the pixel 21. The signal detection circuit 23 can detect a signal output from the pixel 21. The substrate 20 also includes a scintillator 39 (see FIG. 4) that converts radiation into visible light through wavelength conversion.

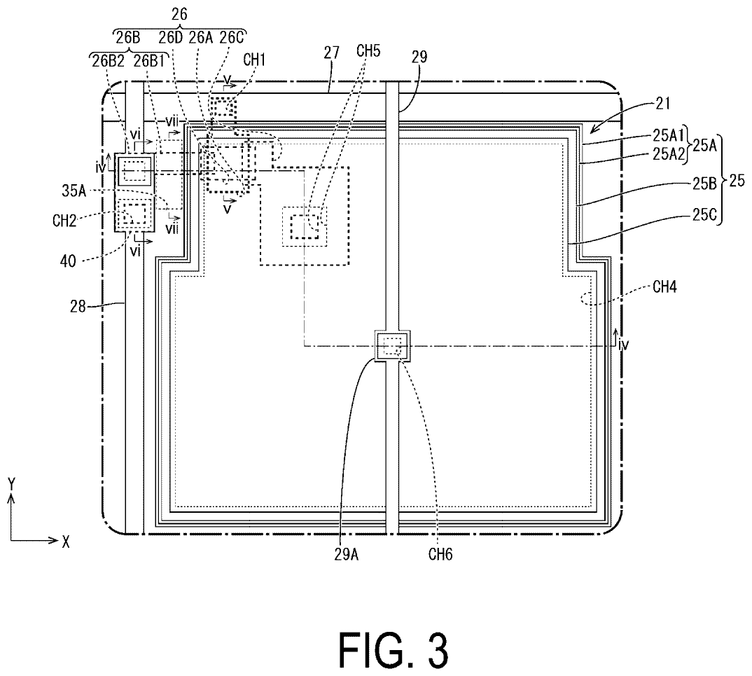

As illustrated in FIG. 3, the pixel 21 includes a photoelectric conversion element (imaging element) 25 and a TFT (switching element) 26 connected to the photoelectric conversion element 25. The photoelectric conversion element 25 is a so-called photodiode and can generate an electric charge upon receiving the visible light that has been wavelength-converted by the scintillator 39. By the TFT 26 being driven at a predetermined timing (e.g., a timing synchronized with a timing at which the radiation is irradiated from the radiation irradiation device 11), the electric charge generated by the photoelectric conversion element 25 can be extracted as a signal. The TFT 26 is located near the upper left corner of the pixel 21 in FIG. 3. The photoelectric conversion element 25 constitutes most of the pixel 21 and overlaps most of the TFT 26.

As illustrated in FIG. 3, a scanning wiring line 27 and a signal wiring line (second circuit element) 28, both of which are connected to the TFT 26, are provided in the imaging region IA of the substrate 20. The scanning wiring line 27 and the signal wiring line 28 are orthogonal to (intersect) each other, and a plurality of the scanning wiring lines 27 and a plurality of the signal wiring lines 28 are disposed so as to surround the TFTs 26 and the photoelectric conversion elements 25. The scanning wiring line 27 extends along the X-axis direction, and the plurality of scanning wiring lines 27 are arranged side by side in the Y-axis direction at intervals. The number of scanning wiring lines 27 provided is equal to the number of pixels 21 provided in the Y-axis direction. The signal wiring line 28 extends along the Y-axis direction, and the plurality of signal wiring lines 28 are arranged side by side in the X-axis direction at intervals. The number of signal wiring lines 28 provided is equal to the number of pixels 21 provided in the X-axis direction. The scanning wiring line 27 is connected to the scanning signal control circuit 22 illustrated in FIG. 2, and can transmit the scanning signal output from the scanning signal control circuit 22 to the TFT 26. The signal wiring line 28 is connected to the signal detection circuit 23 illustrated in FIG. 2, and can transmit the signal output from the TFT 26 (the electric charge generated by the photoelectric conversion element 25) to the signal detection circuit 23. Specific actions will be described. The scanning signal control circuit 22 is controlled by the control device 13 so as to output the scanning signal to the scanning wiring line 27 at the timing synchronized with the timing at which the radiation is irradiated by the radiation irradiation device 11, and so as to drive the TFT 26 connected to the scanning wiring line 27. Then, the electric charge generated as a result of the photoelectric conversion element 25 receiving the visible light that has been obtained by wavelength-converting radiation by the scintillator 39 is transmitted as the signal to the signal wiring lines 28 by the TFT 26, and then detected by the signal detection circuit 23. In this way, the imaging device 12 can generate the radiographic image based on the signals detected by the signal detection circuit 23.

As illustrated in FIG. 3, a power source wiring line (second circuit element) 29 connected to the photoelectric conversion element 25 is provided in the imaging region IA of the substrate 20. The power source wiring line 29 extends along the Y-axis direction in parallel with the signal wiring line 28 and vertically crosses the photoelectric conversion element 25. A plurality of the power source wiring lines 29 are arranged side by side in the X-axis direction at intervals, and are alternately and repeatedly arranged with the signal wiring lines 28 arranged side by side in the X-axis direction at intervals. A reference potential (bias potential) is supplied to the power source wiring line 29 from an external power source via a flexible substrate or the like. The reference potential can be supplied to the photoelectric conversion element 25 by the power source wiring line 29.

Here, mainly with reference to FIG. 4, various films layered on the main surface 20A of the substrate 20 will be described. As illustrated in FIG. 4, in the substrate 20, a first metal film, a gate insulating film 30, a first semiconductor film, a second metal film, a first interlayer insulating film 31, a first flattening film (sixth insulating film) 32, a third metal film, a second interlayer insulating film (seventh insulating film) 33, a fourth metal film, a second semiconductor film, a first transparent electrode film, a third interlayer insulating film (first insulating film) 34, a second flattening film (second insulating film) 35, a fourth interlayer insulating film (third insulating film) 36, a fifth metal film, a second transparent electrode film, a fifth interlayer insulating film (fourth insulating film) 37, a third flattening film (fifth insulating film) 38, and the scintillator 39 are layered in this order from a lower layer side (side closer to the substrate 20).

The first metal film, the second metal film, the third metal film, the fourth metal film, and the fifth metal film are each a single-layer film made of one type of metal material, or a layered film or alloy made of different types of metal materials. Specifically, the first metal film is, for example, a layered film made of W/TaN or the like. The second metal film is, for example, a layered film made of Ti/Al/Ti or the like. The third metal film is, for example, a layered film made of Ti/Al/Ti or the like. The fourth metal film is, for example, a single-layer film made of Ti. The fifth metal film is, for example, a layered film made of Ti/Al/Ti or the like. When the film thicknesses of the second metal film, the third metal film, the fourth metal film, and the fifth metal film are compared, the film thickness increases in the order of the fourth metal film, the third metal film, the second metal film, and the fifth metal film. Therefore, when the sheet resistances of the second metal film, the third metal film, the fourth metal film, and the fifth metal film are compared, the sheet resistance decreases in the order of the fourth metal film, the third metal film, the second metal film, and the fifth metal film.

The first semiconductor film and the second semiconductor film are both made of a semiconductor material. Specifically, the first semiconductor film is made of, for example, an oxide semiconductor or the like. The second semiconductor film is formed by layering an n-type semiconductor layer, an i-type semiconductor layer, and a p-type semiconductor layer in this order from the lower layer side. Each of the n-type semiconductor layer, the i-type semiconductor layer, and the p-type semiconductor layer constituting the second semiconductor film is made of, for example, amorphous silicon. The n-type semiconductor layer and the p-type semiconductor layer both contain impurities, whereas the i-type semiconductor layer is an intrinsic semiconductor containing no impurity. The first transparent electrode film and the second transparent electrode film are both made of a transparent electrode material. Specifically, the first transparent electrode film and the second transparent electrode film are made of, for example, indium tin oxide (ITO) or the like. The scintillator 39 is made of a phosphor that converts radiation into visible light through wavelength conversion. Specifically, the scintillator 39 is made of, for example, cesium iodide (CsI) or the like.

Each of the gate insulating film 30, the first interlayer insulating film 31, the second interlayer insulating film 33, the third interlayer insulating film 34, the fourth interlayer insulating film 36, and the fifth interlayer insulating film 37 is made of an inorganic insulating material (inorganic material). The gate insulating film 30 is, for example, a layered film made of silicon oxide (SiO)/silicon nitride (SiN) or the like. The first interlayer insulating film 31 is, for example, a single-layer film made of SiO or the like. The second interlayer insulating film 33 is a single-layer film made of, for example, SiN, Si, or the like. The third interlayer insulating film 34 contains at least SiN and is, for example, a single-layer film made of SiN. The fourth interlayer insulating film 36 contains at least SiN and is, for example, a single-layer film made of SiN. The fifth interlayer insulating film 37 contains at least SiN and is, for example, a single-layer film made of SiN. Each of the first flattening film 32, the second flattening film 35, and the third flattening film 38 is made of an organic insulating material (organic material) having photosensitivity, and has a film thickness larger than those of the other insulating films 30, 31, 33, 34, 36, and 37 made of the inorganic insulating material. Specifically, each of the insulating films 30, 31, 33, 34, 36, and 37 made of the inorganic insulating material has a thickness of approximately several hundred nm (e.g., 100 nm to 500 nm), whereas each of the flattening films 32, 35, and 38 has a thickness of approximately several μm (e.g., 1 μm to 3 μm). Each of the first flattening film 32, the second flattening film 35, and the third flattening film 38 is made of, for example, a photosensitive acrylic resin or the like. Each of the insulating films 30 to 38 is disposed in a solid state over substantially the entire region of the substrate 20, that is, over the imaging region IA and the non-imaging region NIA.

The relationships between the above-described films layered on the main surface 20A of the substrate 20 and the structures provided in the imaging region IA of the substrate 20 will be described in detail. First, as illustrated in FIGS. 3 and 4, the TFT 26 includes a gate electrode 26A, a source electrode (first circuit element) 26B, a drain electrode 26C, and a semiconductor portion 26D. The gate electrode 26A is made of the first metal film. The gate electrode 26A extends along the Y-axis direction and is disposed such that one end portion thereof (on the lower side in FIG. 3) overlaps the semiconductor portion 26D and the other end portion thereof (on the upper side in FIG. 3) overlaps the scanning wiring line 27. The semiconductor portion 26D is made of the first semiconductor film. The semiconductor portion 26D has a horizontally long shape extending along the X-axis direction, and most of a central portion of the semiconductor portion 26D overlaps a portion of the gate electrode 26A on an upper layer side of the gate electrode 26A with the gate insulating film 30 interposed therebetween. The source electrode 26B and the drain electrode 26C are both made of the second metal film. The source electrode 26B is substantially L-shaped in a plan view, and is formed by connecting a first electrode portion 26B1 extending along the X-axis direction and a second electrode portion 26B2 extending along the Y-axis direction. An end portion, of the first electrode portion 26B1 of the source electrode 26B, on the opposite side to the second electrode portion 26B2 is connected to a portion of the semiconductor portion 26D (an end portion on the left side in FIGS. 3 and 4). The second electrode portion 26B2 of the source electrode 26B is disposed such that substantially the entire region of the second electrode portion 26B2 overlaps the signal wiring line 28 described later. The drain electrode 26C is substantially L-shaped in a plan view, and one end portion thereof (on the left side in FIGS. 3 and 4) is connected to a portion of the semiconductor portion 26D (an end portion on the right in FIGS. 3 and 4) at a position spaced apart from the source electrode 26B in the X-axis direction.

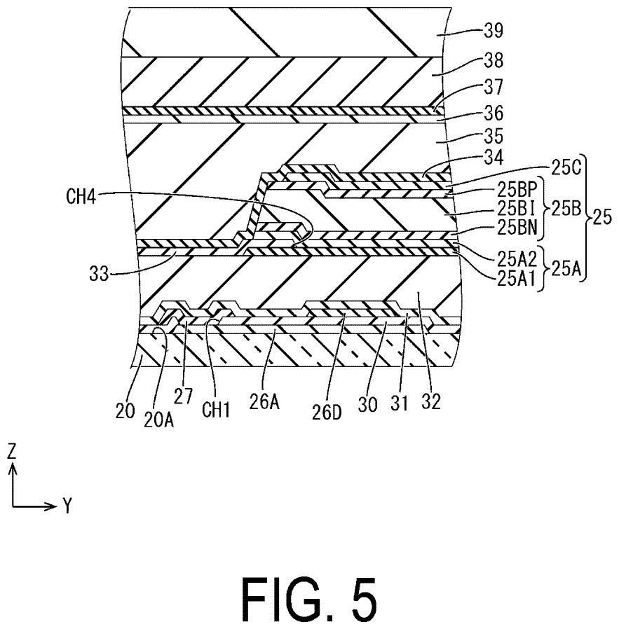

As illustrated in FIGS. 3 and 5, the scanning wiring line 27 is made of a portion of the second metal film different from those of the source electrode 26B and the drain electrode 26C. In this way, compared with a case in which the scanning wiring line is made of one of the first metal film, the third metal film, and the fourth metal film, the wiring line resistance thereof can be reduced. The scanning wiring line 27 extends along the X-axis direction and overlaps a portion of the gate electrode 26A of the TFT 26 on the upper layer side of the gate electrode 26A with the gate insulating film 30 interposed therebetween. At a position, of the gate insulating film 30, overlapping both the gate electrode 26A and the scanning wiring line 27, a first contact hole CH1 is formed as an opening. The gate electrode 26A and the scanning wiring line 27 are connected to each other through the first contact hole CH1. In this way, the scanning signal transmitted by the scanning wiring line 27 is supplied to the gate electrode 26A.

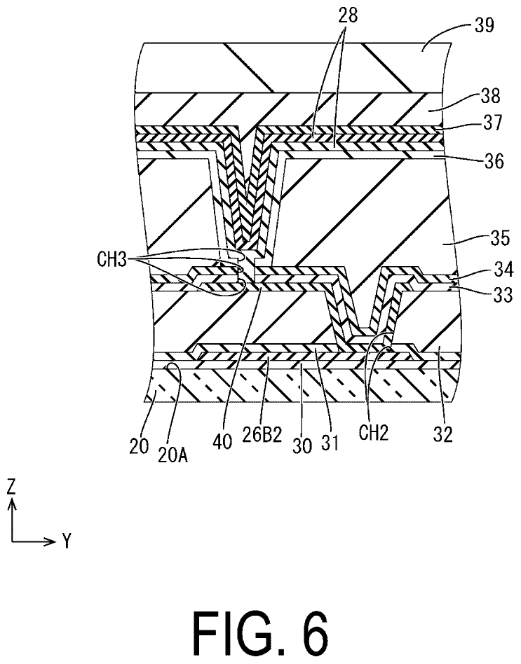

As illustrated in FIGS. 3 and 6, the signal wiring line 28 has a layered structure formed by the fifth metal film and the second transparent electrode film. In this way, compared with a case in which the signal wiring line is made of one of the first metal film, the second metal film, the third metal film, and the fourth metal film, the wiring line resistance thereof can be reduced. The signal wiring line 28 extends along the Y-axis direction. The signal wiring line 28 overlaps the second electrode portion 26B2 of the source electrode 26B provided in the TFT 26 on the upper layer side of the second electrode portion 26B2, with the gate insulating film 30, the first interlayer insulating film 31, the first flattening film 32, the second interlayer insulating film 33, the third interlayer insulating film 34, the second flattening film 35, and the fourth interlayer insulating film 36 interposed therebetween. An intermediate electrode 40 made of the third metal film is provided at a position overlapping both the signal wiring line 28 and the second electrode portion 26B2 of the source electrode 26B. The intermediate electrode 40 has a vertically long rectangular shape extending along the Y-axis direction and overlaps both the second electrode portion 26B2 of the source electrode 26B and the signal wiring line 28. The first interlayer insulating film 31 and the first flattening film 32 are interposed between the intermediate electrode 40 and the second electrode portion 26B2 of the source electrode 26B. A second contact hole CH2 is formed as an opening at a position, of the first interlayer insulating film 31 and the first flattening film 32, overlapping the intermediate electrode 40 and the second electrode portion 26B2 of the source electrode 26B. The intermediate electrode 40 and the second electrode portion 26B2 of the source electrode 26B are connected to each other through the second contact hole CH2. The second interlayer insulating film 33, the third interlayer insulating film 34, the second flattening film 35, and the fourth interlayer insulating film 36 are interposed between the intermediate electrode 40 and the signal wiring line 28. A third contact hole CH3 is formed as an opening at a position, of the second interlayer insulating film 33, the third interlayer insulating film 34, the second flattening film 35, and the fourth interlayer insulating film 36, overlapping the intermediate electrode 40 and the signal wiring line 28. The intermediate electrode 40 and the signal wiring line 28 are connected to each other through the third contact hole CH3. In this way, the signal wiring line 28 is connected to the source electrode 26B via the intermediate electrode 40. Thus, an electric charge present in the source electrode 26B can be transmitted to the signal wiring line 28 as a signal. The signal wiring line 28 intersects the scanning wiring line 27 with the gate insulating film 30, the first interlayer insulating film 31, the first flattening film 32, the second interlayer insulating film 33, the third interlayer insulating film 34, the second flattening film 35, and the fourth interlayer insulating film 36 interposed therebetween. As a result of the plurality of insulating films 30 to 36 being interposed between the scanning wiring line 27 and the signal wiring line 28 in this manner, parasitic capacitance can be reduced.

As illustrated in FIGS. 3 and 4, the power source wiring line 29 has a layered structure formed by portions of the fifth metal film and the second transparent electrode film different from those of the signal wiring line 28. The power source wiring line 29 extends along the Y-axis direction and includes a first widened portion 29A that is partially widened. A main body portion (a portion that is not widened) of the power source wiring line 29 overlaps a portion of the photoelectric conversion element 25, which will be described next. The first widened portion 29A of the power source wiring line 29 overlaps a central portion of the photoelectric conversion element 25. Note that a connection structure between the power source wiring line 29 and the photoelectric conversion element 25 will be described later. Similarly to the signal wiring line 28, the power source wiring line 29 intersects the scanning wiring line 27 with the gate insulating film 30, the first interlayer insulating film 31, the first flattening film 32, the second interlayer insulating film 33, the third interlayer insulating film 34, the second flattening film 35, and the fourth interlayer insulating film 36 interposed therebetween.

As illustrated in FIGS. 3 and 4, the photoelectric conversion element 25 includes a lower electrode 25A, a photoelectric conversion layer 25B layered on the upper layer side of the lower electrode 25A, and an upper electrode 25C layered so as to sandwich the photoelectric conversion layer 25B between the lower electrode 25A and the upper electrode 25C. The lower electrode 25A has a layered structure formed by a first lower electrode 25A1 made of the third metal film and a second lower electrode 25A2 made of the fourth metal film. The second interlayer insulating film 33 is interposed between the first lower electrode 25A1 and the second lower electrode 25A2.

At a position, of the second interlayer insulating film 33, overlapping both the first lower electrode 25A1 and the second lower electrode 25A2, a fourth contact hole CH4 is formed as an opening. The first lower electrode 25A1 and the second lower electrode 25A2 are connected to each other through the fourth contact hole CH4.

As illustrated in FIGS. 3 and 4, the photoelectric conversion element 25 (the lower electrode 25A, the photoelectric conversion layer 25B, and the upper electrode 25C) overlaps most of the TFT 26. Specifically, the photoelectric conversion element 25 overlaps substantially the entire region of each of the gate electrode 26A, the drain electrode 26C, and the semiconductor portion 26D of the TFT 26, and overlaps portions of the source electrode 26B (specifically, a portion, of the first electrode portion 26B1, connected to the semiconductor portion 26D and a portion adjacent thereto). In this way, the photoelectric conversion element 25 occupies most of the region surrounded by the scanning wiring lines 27 and the signal wiring lines 28. Thus, the area of the photoelectric conversion element 25 becomes larger than that in a case in which the photoelectric conversion element 25 does not overlap the TFT 26. As a result, the sensitivity of the photoelectric conversion element 25 can be enhanced. Note that the photoelectric conversion element 25 is disposed so as not to overlap a portion, of the first electrode portion 26B1 of the source electrode 26B, adjacent to the signal wiring line 28, in order to prevent an occurrence of a short-circuit between the intermediate electrode 40 and the first lower electrode 25A1, both of which is made of the third metal film. The first lower electrode 25A1 of the lower electrode 25A overlaps the other end portion (on the right side in FIGS. 3 and 4) of the drain electrode 26C. The first interlayer insulating film 31 and the first flattening film 32 are interposed between the first lower electrode 25A1 and the drain electrode 26C. At a position, of the first interlayer insulating film 31 and the first flattening film 32, overlapping both the first lower electrode 25A1 and the drain electrode 26C, a fifth contact hole CH5 is formed as an opening. The first lower electrode 25A1 and the drain electrode 26C are connected to each other through the fifth contact hole CH5.

As illustrated in FIG. 4, the photoelectric conversion layer 25B has a layered structure formed by an n-type semiconductor portion 25BN made of the n-type semiconductor layer of the second semiconductor film, an i-type semiconductor portion 25BI made of the i-type semiconductor layer of the second semiconductor film, and a p-type semiconductor portion 25BP made of the p-type semiconductor layer of the second semiconductor film, which are layered in this order from the lower layer side. Therefore, the photoelectric conversion element 25 according to the first embodiment is a so-called PIN photodiode. The n-type semiconductor portion 25BN of the photoelectric conversion layer 25B is in contact with the second lower electrode 25A2 of the lower electrode 25A. When the photoelectric conversion layer 25B receives visible light, the photoelectric conversion layer 25B generates an electric charge corresponding to the amount of received light. The electric charge generated in the photoelectric conversion layer 25B is collected by the lower electrode 25A.

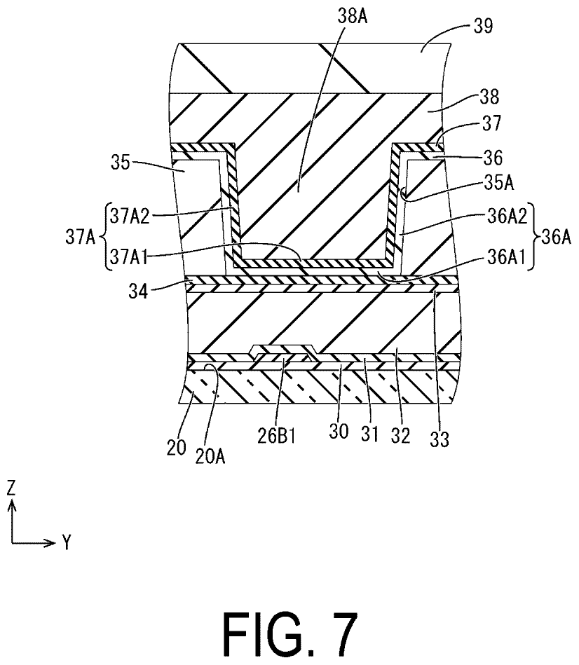

As illustrated in FIGS. 4 and 7, the upper electrode 25C has a single-layer structure formed by the first transparent electrode film. The upper electrode 25C is in contact with the p-type semiconductor portion 25BP of the photoelectric conversion layer 25B. The upper electrode 25C is connected to the first widened portion 29A of the power source wiring line 29. Therefore, the reference potential is supplied to the upper electrode 25C by the power source wiring line 29. The third interlayer insulating film 34, the second flattening film 35, and the fourth interlayer insulating film 36 are interposed between the upper electrode 25C and the first widened portion 29A of the power source wiring line 29. At a position, of the third interlayer insulating film 34, the second flattening film 35, and the fourth interlayer insulating film 36, overlapping the upper electrode 25C and the first widened portion 29A, a sixth contact hole CH6 is formed as an opening. The upper electrode 25C and the first widened portion 29A are connected to each other through the sixth contact hole CH6. The scintillator 39 is provided in a solid state over at least the entire imaging region IA on the third flattening film 38 so as to cover all of the pixels 21. The photoelectric conversion element 25 having such a configuration is substantially entirely covered with the third interlayer insulating film 34 containing SiN as the inorganic insulating material, from the upper layer side. Thus, moisture or the like is made less likely to enter the photoelectric conversion element 25.

During or after the manufacturing of the imaging device 12 having the configuration described above, it may be inspected whether or not a defect has occurred in any one of the wiring lines 27 to 29, the photoelectric conversion elements 25, and the TFTs 26 provided on the substrate 20. As a result of the inspection, when a defect is detected, laser repair is performed in which laser light is irradiated onto the vicinity of a defective portion of the substrate 20. For example, when a malfunction occurs in a predetermined photoelectric conversion element 25, the laser light is irradiated onto a portion of the source electrode 26B of the TFT 26 in order to cut off the source electrode 26B. In this way, the signal from the malfunctioning photoelectric conversion element 25 is not transmitted to the signal wiring line 28, and thus the signal is not detected by the signal detection circuit 23. In related art, when performing the laser repair as described above, laser light is irradiated onto the second flattening film 35 containing the organic insulating material. As a result, a film defect occurs in the second flattening film 35. When the film defect occurs in the second flattening film 35, moisture or the like may diffuse into the second flattening film 35 from the defective portion. If the moisture or the like diffuses into the second flattening film 35, there is a risk that characteristics of the photoelectric conversion elements 25 for which no malfunction has occurred (which are not targeted by the laser repair) may deteriorate due to the moisture or the like. Although the photoelectric conversion element 25 is covered with the third interlayer insulating film 34 from the upper layer side, an outer peripheral edge portion of the photoelectric conversion element 25 has fine irregularities on the surface thereof, which is also formed as a steeply inclined surface. Thus, the coverage of the third interlayer insulating film 34 is poor. Therefore, there is a concern that the moisture or the like diffused in the second flattening film 35 may enter the photoelectric conversion element 25.

In light of the above-described concern, in the first embodiment, as illustrated in FIGS. 3, 4, and 7, the second flattening film 35 is provided with a first opening 35A overlapping a portion of the source electrode 26B. As illustrated in FIGS. 4 and 7, the first opening 35A penetrates the second flattening film 35. The bottom surface of an opening edge of the first opening 35A is formed by the front surface of the third interlayer insulating film 34, and the side surface of the opening edge is an inclined surface inclined with respect to the Z-axis direction (the normal direction of the main surface 20A of the substrate 20). As illustrated in FIG. 3, when the second flattening film 35 is viewed in a plan view, the first opening 35A is provided over a range having a vertically long rectangular shape. The first opening 35A extends along the Y-axis direction and intersects the first electrode portion 26B1, which is a portion, of the source electrode 26B, extending along the X-axis direction. The first opening 35A is provided over a wider range than the first electrode portion 26B1 in the Y-axis direction, and includes a portion overlapping the first electrode portion 26B1, a portion displaced to one side (upper side in FIG. 3) in the Y-axis direction with respect to the first electrode portion 26B1, and a portion displaced to the other side (lower side in FIG. 3) in the Y-axis direction with respect to the first electrode portion 26B1. The first opening 35A is interposed between the signal wiring line 28 and the photoelectric conversion element 25 in the X-axis direction. In other words, the first opening 35A overlaps a portion, of the first electrode portion 26B1 of the source electrode 26B, not overlapping the photoelectric conversion element 25. According to such a configuration, when performing the laser repair, if laser light is irradiated into the first opening 35A, the laser light is irradiated onto the portion, of the first electrode portion 26B1 of the source electrode 26B, not overlapping the photoelectric conversion element 25. The laser light irradiated onto the source electrode 26B passes through the first opening 35A and is not irradiated onto the second flattening film 35. Therefore, the film defect caused by the irradiation of the laser light is prevented from occurring in the second flattening film 35. Since the laser light irradiated onto the source electrode 26B is prevented from being irradiated onto the photoelectric conversion element 25, problems such as a short circuit between the source electrode 26B and the photoelectric conversion element 25 caused by the irradiation of the laser light are less likely to occur.

As illustrated in FIGS. 4 and 7, the fourth interlayer insulating film 36 disposed on the upper layer side of the second flattening film 35 includes a first covering portion 36A covering the opening edge of the first opening 35A in the second flattening film 35. Specifically, the fourth interlayer insulating film 36 covers substantially the entire second flattening film 35 from the upper layer side, and a portion of the fourth interlayer insulating film 36 forms the first covering portion 36A covering the opening edge of the first opening 35A in the second flattening film 35. The first covering portion 36A covers the entire bottom surface and side surface of the opening edge of the first opening 35A from the upper layer side, and has a bottomed cylindrical shape as a whole. The first covering portion 36A includes a first bottom portion 36A1 covering the bottom surface of the opening edge of the first opening 35A, and a first side portion 36A2 covering the side surface of the opening edge of the first opening 35A. The first bottom portion 36A1 is in contact with the front surface of the third interlayer insulating film 34. According to such a configuration, a region inside the first opening 35A in the second flattening film 35, that is, a range irradiated with the laser light can be surrounded by the first covering portion 36A. Therefore, even if moisture or the like enters the region inside the first opening 35A due to the irradiation of the laser light, the first covering portion 36A of the fourth interlayer insulating film 36 containing the inorganic insulating material makes it less likely for the moisture or the like to diffuse into the second flattening film 35. As a result, it is possible to make it less likely for the characteristics of the photoelectric conversion elements 25, for which no malfunction has occurred (which are not targeted by the laser repair), to deteriorate. In the first embodiment, since the fourth interlayer insulating film 36 is the single-layer film containing SiN as the inorganic insulating material, the first covering portion 36A can effectively suppress the moisture or the like from diffusing into the second flattening film 35.

In addition, as illustrated in FIGS. 4 and 7, the fifth interlayer insulating film 37 includes a second covering portion 37A covering the first covering portion 36A. Specifically, the fifth interlayer insulating film 37 covers, from the upper layer side, the fourth interlayer insulating film 36 and the structures made of the fifth metal film and the second transparent electrode film (the signal wiring lines 28, the power source wiring lines 29, and the like), and a portion of the fifth interlayer insulating film 37 forms the second covering portion 37A covering the first covering portion 36A inside the first opening 35A in the second flattening film 35. The second covering portion 37A is disposed inside the first opening 35A so as to cover the entire first covering portion 36A from the upper layer side and has a bottomed cylindrical shape as a whole. The second covering portion 37A includes a second bottom portion 37A1 covering the first bottom portion 36A1 of the first covering portion 36A, and a second side portion 37A2 covering the first side portion 36A2 of the first covering portion 36A. According to such a configuration, the region inside the first opening 35A in the second flattening film 35, that is, the range irradiated with the laser light can be doubly surrounded by the second covering portion 37A of the fifth interlayer insulating film 37 as well as the first covering portion 36A of the fourth interlayer insulating film 36. Therefore, even if moisture or the like enters the region inside the first opening 35A due to the irradiation of the laser light, the first covering portion 36A and the second covering portion 37A of the fourth interlayer insulating film 36 and the fifth interlayer insulating film 37 each containing the inorganic insulating material can make it even more less likely for the moisture or the like to diffuse into the second flattening film 35. In the first embodiment, since the fifth interlayer insulating film 37 is the single-layer film containing SiN as the inorganic insulating material, the second covering portion 37A can effectively suppress the moisture or the like from diffusing into the second flattening film 35. In addition, by covering the signal wiring lines 28 and the power source wiring lines 29 with the fifth interlayer insulating film 37 from the upper layer side, the moisture or the like can be made less likely to enter the signal wiring lines 28 and the power source wiring lines 29.

Further, as illustrated in FIGS. 4 and 7, the third flattening film 38 includes a first filling portion 38A filled in the first opening 35A. Specifically, the third flattening film 38 covers substantially the entire region of the fifth interlayer insulating film 37 from the upper layer side, and a portion of the third flattening film 38 forms the first filling portion 38A filled in the first opening 35A in the second flattening film 35. Since the first filling portion 38A is a portion of the third flattening film 38, the first filling portion 38A covers the entire second covering portion 37A from the upper layer side inside the first opening 35A and flattens a recessed portion formed by the first opening 35A. At the time of laser repair, laser light is irradiated onto the first filling portion 38A filled in the first opening 35A. Then, a film defect may occur in the first filling portion 38A of the third flattening film 38 made of the organic insulating material, and moisture or the like may enter the defective portion. Even in such a case, since the first filling portion 38A is surrounded by the first covering portion 36A of the fourth interlayer insulating film 36 covering the opening edge of the first opening 35A, even if the moisture or the like enters the defective portion of the first filling portion 38A, the moisture or the like can be made less likely to diffuse into the second flattening film 35.

As described above, the imaging device 12 according to the first embodiment includes the photoelectric conversion element (imaging element) 25, the source electrode 26B serving as the first circuit element and disposed on the lower layer side of the photoelectric conversion element 25, the third interlayer insulating film (first insulating film) 34 disposed on the upper layer side of the photoelectric conversion element 25, the second flattening film (second insulating film) 35 disposed on the upper layer side of the third interlayer insulating film 34, and the fourth interlayer insulating film (third insulating film) 36 disposed on the upper layer side of the second flattening film 35. Each of the third interlayer insulating film 34 and the fourth interlayer insulating film 36 contains the inorganic insulating material. The second flattening film 35 contains the organic insulating material and is provided with the first opening 35A overlapping the portion of the source electrode 26B serving as the first circuit element. The fourth interlayer insulating film 36 includes the first covering portion 36A covering the opening edge of the first opening 35A in the second flattening film 35.

Since the third interlayer insulating film 34 disposed on the upper layer side of the photoelectric conversion element 25 contains the inorganic insulating material, moisture or the like can be made less likely to enter the photoelectric conversion element 25. When the laser repair is performed on the portion of the source electrode 26B serving as the first circuit element, laser light is irradiated onto the portion of the source electrode 26B serving as the first circuit element. When a film defect caused by the irradiation of the laser light occurs in the second flattening film 35 containing the organic insulating material, there is a concern that moisture or the like diffuses into the second flattening film 35 from the defective portion. In this regard, since the second flattening film 35 is provided with the first opening 35A overlapping the portion of the source electrode 26B serving as the first circuit element, the laser light irradiated onto the portion of the source electrode 26B serving as the first circuit element passes through the first opening 35A of the second flattening film 35. Thus, the film defect is prevented from occurring in the second flattening film 35. In addition, since the fourth interlayer insulating film 36 includes the first covering portion 36A covering the opening edge of the first opening 35A in the second flattening film 35, the region inside the first opening 35A, that is, the range irradiated with the laser light can be surrounded by the first covering portion 36A of the fourth interlayer insulating film 36. Therefore, even if moisture or the like enters the region inside the first opening 35A due to the irradiation of the laser light, the first covering portion 36A of the fourth interlayer insulating film 36 containing the inorganic insulating material makes it less likely for the moisture or the like to diffuse into the second flattening film 35. In this way, it is possible to make it less likely for the characteristics of the photoelectric conversion elements 25 to deteriorate.

Further, the imaging device 12 includes the signal wiring lines 28 and the power source wiring lines 29 serving as the second circuit elements and disposed on the upper layer side of the fourth interlayer insulating film 36, and the fifth interlayer insulating film (fourth insulating film) 37 disposed on the upper layer side of the signal wiring lines 28 and the power source wiring lines 29 serving as the second circuit elements. The fifth interlayer insulating film 37 contains the inorganic insulating material and includes the second covering portion 37A covering the first covering portion 36A. Since the fifth interlayer insulating film 37 disposed on the upper layer side of the signal wiring lines 28 and the power source wiring line 29 serving as the second circuit elements contains the inorganic insulating material, moisture or the like can be made less likely to enter the signal wiring lines 28 and the power source wiring lines 29 serving as the second circuit elements. Then, the region inside the first opening 35A in the second flattening film 35, that is, the range irradiated with the laser light can be surrounded by the second covering portion 37A of the fifth interlayer insulating film 37 as well as the first covering portion 36A of the fourth interlayer insulating film 36. Therefore, even if moisture or the like enters the region inside the first opening 35A due to the irradiation of the laser light, the first covering portion 36A and the second covering portion 37A of the fourth interlayer insulating film 36 and the fifth interlayer insulating film 37 each containing the inorganic insulating material can make it even more less likely for the moisture or the like to diffuse into the second flattening film 35.

Further, the imaging device 12 includes the third flattening film (fifth insulating film) 38 disposed on the upper layer side of the fourth interlayer insulating film 36, and the third flattening film 38 contains the organic insulating material and includes the first filling portion 38A filled in the first opening 35A. Since the first filling portion 38A of the third flattening film 38 is filled in the first opening 35A in the second flattening film 35, when laser light is irradiated onto the portion of the source electrode 26B serving as the first circuit element, the laser light is also irradiated onto the first filling portion 38A. When the laser light is irradiated onto the first filling portion 38A, a film defect may occur in the first filling portion 38A, and moisture or the like may enter the defective portion. Even in such a case, since the first filling portion 38A is surrounded by the first covering portion 36A of the fourth interlayer insulating film 36 covering the opening edge of the first opening 35A, even if the moisture or the like enters the defective portion of the first filling portion 38A, the moisture or the like can be made less likely to diffuse into the second flattening film 35.

Further, each of the third interlayer insulating film 34 and the fourth interlayer insulating film 36 contains silicon nitride as the inorganic insulating material. In this way, even if moisture or the like enters the region inside the first opening 35A due to the irradiation of the laser light, the first covering portion 36A of the fourth interlayer insulating film 36 containing silicon nitride as the inorganic insulating material makes it even less likely for the moisture or the like to diffuse into the second flattening film 35.

The imaging device 12 further includes the TFT 26 disposed on the lower layer side of the photoelectric conversion element 25. The TFT 26 includes the gate electrode 26A, the semiconductor portion 26D overlapping the gate electrode 26A while being spaced apart from the gate electrode 26A, the source electrode 26B connected to the semiconductor portion 26D, and the drain electrode 26C connected to the semiconductor portion 26D at a position spaced apart from the source electrode 26B. The photoelectric conversion element 25 does not overlap at least a portion of the source electrode 26B and overlaps the gate electrode 26A, the semiconductor portion 26D, and the drain electrode 26C, the source electrode 26B serving as the first circuit element. When the laser light is irradiated onto the portion, of the source electrode 26B serving as the first circuit element, not overlapping the photoelectric conversion elements 25, the source electrode 26B is disconnected and the TFT 26 becomes inoperable. Since the photoelectric conversion element 25 does not overlap the portion, of the source electrode 26B, irradiated with the laser light, a short circuit between a portion of the photoelectric conversion element 25 and the source electrode 26B due to the irradiation of the laser light is made less likely to occur. In addition, since the photoelectric conversion element 25 overlaps the gate electrode 26A, the semiconductor portion 26D, and the drain electrode 26C, the area of the photoelectric conversion element 25 becomes larger than that in the case in which the photoelectric conversion element 25 does not overlap the TFT 26. Thus, the sensitivity related to imaging is increased.

### Second Embodiment

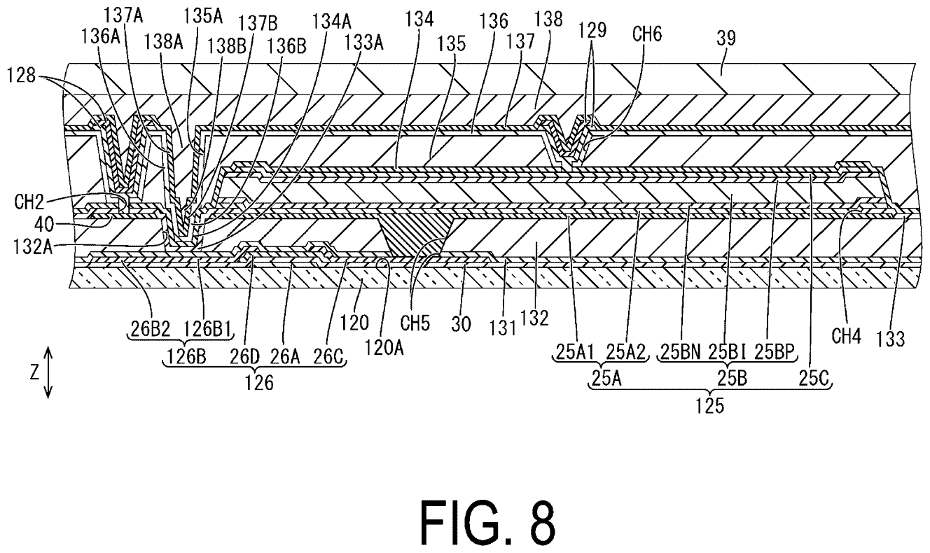

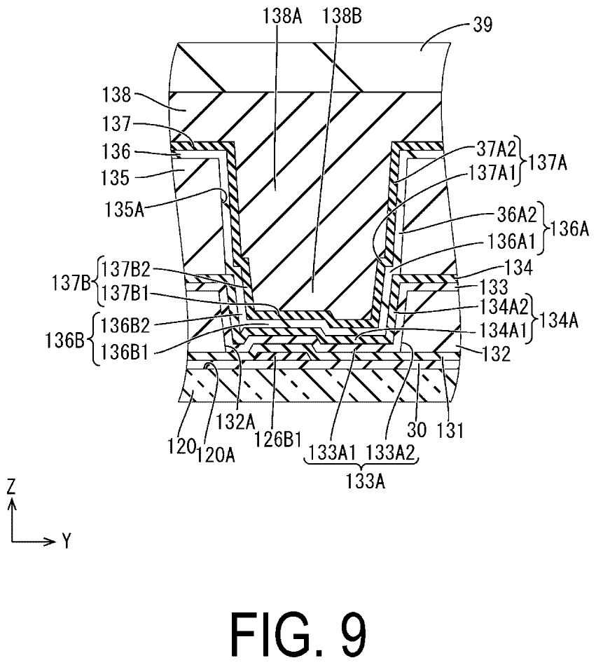

A second embodiment will be described with reference to FIG. 8 or 9. In the second embodiment, a case will be described in which configurations of a first flattening film 132 and the like are changed from those of the first embodiment. Note that repetitive descriptions of structures, actions, and effects similar to those of the first embodiment described above will be omitted.

As illustrated in FIGS. 8 and 9, the first flattening film 132 according to the second embodiment is provided with a second opening 132A overlapping a first opening 135A. The second opening 132A penetrates the first flattening film 132. The bottom surface of an opening edge of the second opening 132A is formed by the front surface of a first interlayer insulating film 131, and the side surface of the opening edge is an inclined surface inclined with respect to the Z-axis direction (the normal direction of a main surface 120A of a substrate 120). The formation range of the second opening 132A in a plan view is substantially the same as the formation range of a first opening 135A (see FIG. 8). In other words, the second opening 132A intersects a first electrode portion 126B1 that is a portion, of a source electrode 126B, extending along the X-axis direction and overlaps a portion, of the first electrode portion 126B1, not overlapping a photoelectric conversion element 125. According to such a configuration, at the time of laser repair, when the laser light is irradiated onto the portion, of the first electrode portion 126B1 of the source electrode 126B, not overlapping the photoelectric conversion element 125, the laser light passes through the first opening 135A and the second opening 132A. Thus, the laser light is not irradiated onto the first flattening film 132 and a second flattening film 135. Therefore, a film defect caused by the irradiation of the laser light is prevented from occurring in the first flattening film 132 and the second flattening film 135.

Then, as illustrated in FIGS. 8 and 9, a fourth interlayer insulating film 136 disposed on the upper layer side of the first flattening film 132 includes a third covering portion 136B covering the opening edge of the second opening 132A in the first flattening film 132. Specifically, the third covering portion 136B is continuous with the first covering portion 136A covering the inside of the first opening 135A, and covers the opening edge of the second opening 132A in the first flattening film 132. Similarly to the first covering portion 136A, the third covering portion 136B has a bottomed cylindrical shape as a whole and includes a third bottom portion 136B1 covering the bottom surface of the opening edge of the second opening 132A and a third side portion 136B2 covering the side surface of the opening edge of the second opening 132A. The third side portion 136B2 is continuous with a first bottom portion 136A1 of the first covering portion 136A. According to such a configuration, a region inside the second opening 132A in the first flattening film 132, that is, the range irradiated with the laser light can be surrounded by the third covering portion 136B. Therefore, even if moisture or the like enters the region inside the second opening 132A due to the irradiation of the laser light, the moisture or the like can be made less likely to diffuse into the first flattening film 132 due to the third covering portion 136B of the fourth interlayer insulating film 136 containing an inorganic insulating material. In this way, it is possible to make it less likely for the characteristics of the TFTs 126 and the photoelectric conversion elements 125, for which no malfunction has occurred (which are not targeted by the laser repair), to deteriorate. In the second embodiment, since the fourth interlayer insulating film 136 is a single-layer film containing SiN as the inorganic insulating material, the third covering portion 136B can effectively suppress the moisture or the like from diffusing into the first flattening film 132.

In addition, as illustrated in FIGS. 8 and 9, the third interlayer insulating film 134 disposed on the upper layer side of the first flattening film 132 and on the lower layer side of the fourth interlayer insulating film 136 includes a fourth covering portion 134A covering the opening edge of the second opening 132A in the first flattening film 132. Specifically, the third interlayer insulating film 134 covers the second interlayer insulating film 133 and the photoelectric conversion elements 125 from the upper layer side, and a portion of the third interlayer insulating film 134 forms the fourth covering portion 134A covering the opening edge of the second opening 132A in the first flattening film 132. The fourth covering portion 134A of the third interlayer insulating film 134 is covered with the third covering portion 136B of the fourth interlayer insulating film 136 from the upper layer side. Similarly to the third covering portion 136B, the fourth covering portion 134A has a bottomed cylindrical shape as a whole and includes a fourth bottom portion 134A1 disposed on the lower layer side of the third bottom portion 136B1 and a fourth side portion 134A2 disposed on the lower layer side of the third side portion 136B2. According to such a configuration, the region inside the second opening 132A in the first flattening film 132, that is, the range irradiated with the laser light can be doubly surrounded by the fourth covering portion 134A of the third interlayer insulating film 134 as well as the third covering portion 136B of the fourth interlayer insulating film 136. Therefore, even if moisture or the like enters the region inside the second opening 132A due to the irradiation of the laser light, the moisture or the like can be made even less likely to diffuse into the first flattening film 132 due to the third covering portion 136B and the fourth covering portion 134A of the fourth interlayer insulating film 136 and the third interlayer insulating film 134 each containing an inorganic insulating material.

Furthermore, as illustrated in FIGS. 8 and 9, the fifth interlayer insulating film 137 disposed on the upper layer side of the fourth interlayer insulating film 136 and on the lower layer side of the third flattening film 138 includes a fifth covering portion 137B covering the third covering portion 136B. Specifically, the fifth covering portion 137B is continuous with the second covering portion 137A covering the inside of the first opening 135A and covers the opening edge of the second opening 132A in the first flattening film 132. Similarly to the second covering portion 137A, the fifth covering portion 137B has a bottomed cylindrical shape as a whole and includes a fifth bottom portion 137B1 covering the bottom surface of the opening edge of the second opening 132A and a fifth side portion 137B2 covering the side surface of the opening edge of the second opening 132A. The fifth side portion 137B2 is continuous with the second bottom portion 137A1 of the second covering portion 137A. According to such a configuration, the region inside the second opening 132A in the first flattening film 132, that is, the range irradiated with the laser light can be triply surrounded by the fifth covering portion 137B of the fifth interlayer insulating film 137 as well as the third covering portion 136B and the fourth covering portion 134A. Therefore, even if moisture or the like enters the region inside the second opening 132A due to the irradiation of the laser light, the moisture or the like can be made even less likely to diffuse into the first flattening film 132 due to the third covering portion 136B, the fourth covering portion 134A, and the fifth covering portion 137B of the fourth interlayer insulating film 136, the third interlayer insulating film 134, and the fifth interlayer insulating film 137 each containing an inorganic insulating material.

As illustrated in FIGS. 8 and 9, the second interlayer insulating film 133 disposed on the upper layer side of the first flattening film 132 and on the lower layer side of the third interlayer insulating film 134 includes a sixth covering portion 133A covering the opening edge of the second opening 132A in the first flattening film 132. Specifically, the second interlayer insulating film 133 covers the first flattening film 132 from the upper layer side except for a range overlapping the fourth contact hole CH4, and a portion of the second interlayer insulating film 133 forms the sixth covering portion 133A covering the opening edge of the second opening 132A in the first flattening film 132. The sixth covering portion 133A covers the entire bottom surface and side surface of the opening edge of the second opening 132A from the upper layer side, and has a bottomed cylindrical shape as a whole. The sixth covering portion 133A includes a sixth bottom portion 133A1 covering the bottom surface of the opening edge of the second opening 132A and a sixth side portion 133A2 covering the side surface of the opening edge of the second opening 132A. The sixth bottom portion 133A1 is in contact with the front surface of the first interlayer insulating film 131. The sixth covering portion 133A of the second interlayer insulating film 133 is covered with the fourth covering portion 134A of the third interlayer insulating film 134. According to such a configuration, the region inside the second opening 132A in the first flattening film 132, that is, the range irradiated with the laser light can be quadruply surrounded by the sixth covering portion 133A as well as the third covering portion 136B, the fourth covering portion 134A, and the fifth covering portion 137B. Therefore, even if moisture or the like enters the region inside the second opening 132A due to the irradiation of the laser light, the moisture or the like can be made even less likely to diffuse into the first flattening film 132 due to the third covering portion 136B, the fourth covering portion 134A, the fifth covering portion 137B, and the sixth covering portion 133A of the fourth interlayer insulating film 136, the third interlayer insulating film 134, the fifth interlayer insulating film 137, and the second interlayer insulating film 133 each containing an inorganic insulating material.

As illustrated in FIGS. 8 and 9, the third flattening film 138 includes a second filling portion 138B filled in the second opening 132A in addition to the first filling portion 138A filled in the first opening 135A. Specifically, the second filling portion 138B is continuous with the bottom surface of the first filling portion 138A filled in the first opening 135A, protrudes from the first filling portion 138A toward the back side, and is filled in the second opening 132A in the first flattening film 132. Since the second filling portion 138B is a portion of the third flattening film 138, the second filling portion 138B covers the entire fifth covering portion 137B from the upper layer side inside the second opening 132A, and flattens a recessed portion formed by the second opening 132A. At the time of laser repair, laser light is irradiated onto the first filling portion 138A filled in the first opening 135A and the second filling portion 138B filled in the second opening 132A. Then, film defects may occur in the first filling portion 138A and the second filling portion 138B of the third flattening film 138 made of an organic insulating material, and moisture or the like may enter the defective portions. Even in such a case, since the first filling portion 138A is surrounded by the first covering portion 136A, of the fourth interlayer insulating film 136, covering the opening edge of the first opening 135A, even if the moisture or the like enters the defective portion of the first filling portion 138A, the moisture or the like can be made less likely to diffuse into the second flattening film 135. Similarly, since the second filling portion 138B is surrounded by the third covering portion 136B, of the fourth interlayer insulating film 136, covering the opening edge of the second opening 132A, even if the moisture or the like enters the defective portion of the second filling portion 138B, the moisture or the like can be made less likely to diffuse into the first flattening film 132.

As described above, the second embodiment includes the TFTs (switching elements) 126 disposed on the lower layer side of the photoelectric conversion elements 125, and the first flattening film (sixth insulating film) 132 disposed on the upper layer side of the TFTs 126 and on the lower layer side of the photoelectric conversion elements 125. The TFT 126 includes the source electrode 126B serving as the first circuit element. The first flattening film 132 contains an organic insulating material and is provided with the second opening 132A overlapping the first opening 135A. The fourth interlayer insulating film 136 includes the third covering portion 136B covering the opening edge of the second opening 132A in the first flattening film 132. By irradiating laser light onto a portion of the source electrode 126B serving as the first circuit element, the TFT 126 can be made inoperable. Since the second opening 132A overlapping the first opening 135A is provided in the first flattening film 132 disposed on the upper layer side of the TFT 126 and on the lower layer side of the photoelectric conversion element 125, the laser light irradiated onto the portion of the source electrode 126B serving as the first circuit element passes through the second opening 132A of the first flattening film 132. Thus, the film defect is prevented from occurring in the first flattening film 132. In addition, since the fourth interlayer insulating film 136 includes the third covering portion 136B covering the opening edge of the second opening 132A in the first flattening film 132, the region inside the second opening 132A, that is, the range irradiated with the laser light can be surrounded by the third covering portion 136B of the fourth interlayer insulating film 136. Therefore, even if moisture or the like enters the region inside the second opening 132A due to the irradiation of the laser light, the moisture or the like can be made less likely to diffuse into the first flattening film 132 due to the third covering portion 136B of the fourth interlayer insulating film 136 containing an inorganic insulating material. In this way, it is possible to make it less likely for the characteristics of the TFTs 126 to deteriorate.

The third interlayer insulating film 134 includes the fourth covering portion 134A covering the opening edge of the second opening 132A in the first flattening film 132, and the third covering portion 136B covers the fourth covering portion 134A. In this way, the region inside the second opening 132A in the first flattening film 132, that is, the range irradiated with the laser light can be surrounded by the fourth covering portion 134A of the third interlayer insulating film 134 as well as the third covering portion 136B of the fourth interlayer insulating film 136. Therefore, even if moisture or the like enters the region inside the second opening 132A due to the irradiation of the laser light, the moisture or the like can be made even less likely to diffuse into the first flattening film 132 due to the third covering portion 136B and the fourth covering portion 134A of the fourth interlayer insulating film 136 and the third interlayer insulating film 134 each containing an inorganic insulating material.

The second embodiment further includes the signal wiring lines 128 and the power source wiring lines 129, both of which are disposed on the upper layer side of the fourth interlayer insulating film 136 and serve as the second circuit elements, and the fifth interlayer insulating film 137 disposed on the upper layer side of the signal wiring lines 128 and the power source wiring lines 129 serving as the second circuit elements. The fifth interlayer insulating film 137 contains an inorganic insulating material and includes the fifth covering portion 137B covering the third covering portion 136B. Since the fifth interlayer insulating film 137 disposed on the upper layer side of the signal wiring lines 128 and the power source wiring lines 129 serving as the second circuit elements contains the inorganic insulating material, moisture or the like can be made less likely to enter the signal wiring lines 128 and the power source wiring lines 129 serving as the second circuit elements. The region inside the second opening 132A in the first flattening film 132, that is, the range irradiated with the laser light can be surrounded by the fifth covering portion 137B of the fifth interlayer insulating film 137 as well as the third covering portion 136B of the fourth interlayer insulating film 136. Therefore, even if moisture or the like enters the region in the second opening 132A due to the irradiation of the laser light, the moisture or the like can be made even less likely to diffuse into the first flattening film 132 due to the third covering portion 136B and the fifth covering portion 137B of the fourth interlayer insulating film 136 and the fifth interlayer insulating film 137 each containing the inorganic insulating material.

The second embodiment further includes the second interlayer insulating film (seventh insulating film) 133 disposed on the upper layer side of the first flattening film 132. The second interlayer insulating film 133 contains an inorganic insulating material and includes the sixth covering portion 133A covering the opening edge of the second opening 132A in the first flattening film 132. In this way, the region inside the second opening 132A in the first flattening film 132, that is, the range irradiated with the laser light can be surrounded by the sixth covering portion 133A of the second interlayer insulating film 133 as well as the third covering portion 136B of the fourth interlayer insulating film 136. Therefore, even if moisture or the like enters the region inside the second opening 132A due to the irradiation of the laser light, the moisture or the like can be made even less likely to diffuse into the first flattening film 132 due to the third covering portion 136B and the sixth covering portion 133A of the fourth interlayer insulating film 136 and the second interlayer insulating film 133 each containing the inorganic insulating material.

The second embodiment further includes the third flattening film 138 on the upper layer side of the fourth interlayer insulating film 136. The third flattening film 138 contains an organic insulating material and includes the first filling portion 138A filled in the first opening 135A and the second filling portion 138B filled in the second opening 132A. Since the first filling portion 138A is filled in the first opening 135A in the second flattening film 135, and the second filling portion 138B is filled in the second opening 132A in the first flattening film 132, when laser light is irradiated onto a portion of the source electrode 126B serving as the first circuit element, the laser light is also irradiated onto the first filling portion 138A and the second filling portion 138B. When the laser light is irradiated onto the first filling portion 138A and the second filling portion 138B, film defects may occur in the first filling portion 138A and the second filling portion 138B, and moisture or the like may enter the defective portions. Even in such a case, since the first filling portion 138A is surrounded by the first covering portion 136A, of the fourth interlayer insulating film 136, covering the opening edge of the first opening 135A, even if the moisture or the like enters the defective portion of the first filling portion 138A, the moisture or the like can be made less likely to diffuse into the second flattening film 135. Similarly, since the second filling portion 138B is surrounded by the third covering portion 136B, of the fourth interlayer insulating film 136, covering the opening edge of the second opening 132A, even if the moisture or the like enters the defective portion of the second filling portion 138B, the moisture or the like can be made less likely to diffuse into the first flattening film 132.

### Third Embodiment

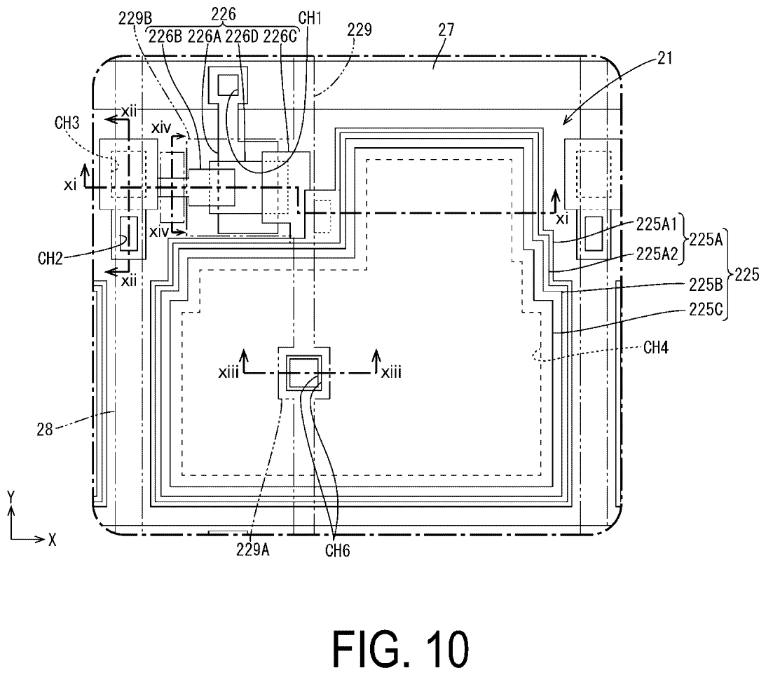

A third embodiment will be described with reference to FIGS. 10 to 14. In the third embodiment, a case will be described in which the formation range of a photoelectric conversion element 225 and configurations of a power source wiring line 229 and the like are changed from those of the first embodiment. Further, the first flattening film 32 is omitted in the third embodiment. Note that repetitive descriptions of structures, actions, and effects similar to those of the first embodiment described above will be omitted.

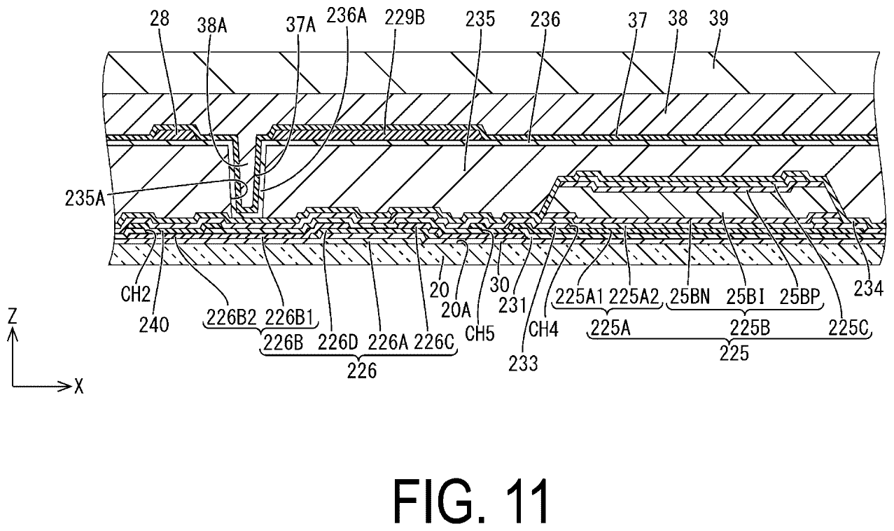

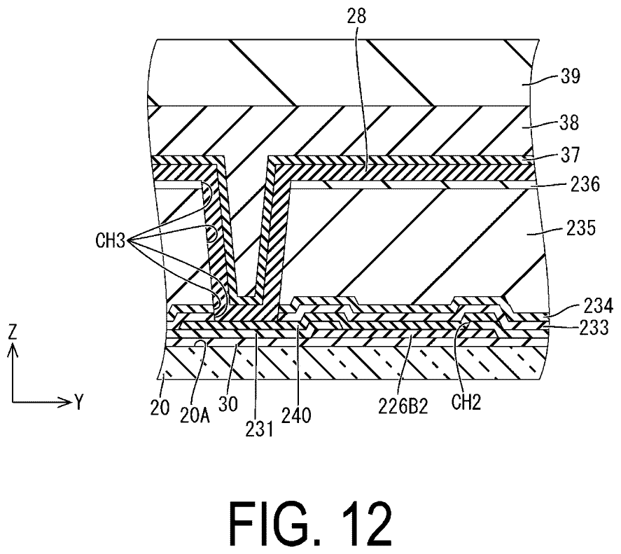

As illustrated in FIGS. 10 and 11, in the photoelectric conversion element 225 according to the third embodiment, at least a second lower electrode 225A2, a photoelectric conversion layer 225B, and an upper electrode 225C do not overlap a TFT 226. Specifically, of the lower electrode 225A constituting the photoelectric conversion element 225, a first lower electrode 225A1 is extended further than the second lower electrode 225A2, the photoelectric conversion layer 225B, and the upper electrode 225C, and the extended portion overlaps another end portion (on the right side in FIGS. 10 and 11) of a drain electrode 226C of the TFT 226. The first lower electrode 225A1 does not overlap a portion of the drain electrode 226C connected to a semiconductor portion 226D and a portion adjacent thereto. In the third embodiment, since the first flattening film 32 (see FIG. 4) described in the first embodiment is omitted, the first lower electrode 225A1 is disposed on a first interlayer insulating film 231, and the first interlayer insulating film 231 is interposed between the first lower electrode 225A1 and the drain electrode 226C. Therefore, the fifth contact hole CH5 for connecting the first lower electrode 225A1 and the drain electrode 226C is formed as an opening only in the first interlayer insulating film 231. In the third embodiment, since the first flattening film 32 is omitted, as illustrated in FIG. 12, an intermediate electrode 240 is disposed on the first interlayer insulating film 231, and the first interlayer insulating film 231 is interposed between the intermediate electrode 240 and a second electrode portion 226B2 of a source electrode 226B. Therefore, the second contact hole CH2 for connecting the intermediate electrode 240 and the second electrode portion 226B2 of the source electrode 226B is formed as an opening only in the first interlayer insulating film 231.

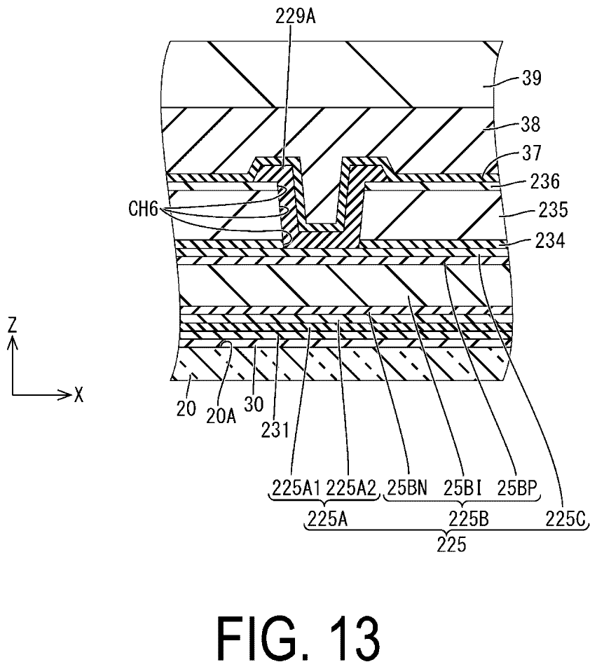

As illustrated in FIGS. 10 and 11, the power source wiring line 229 includes a second widened portion 229B in addition to a first widened portion 229A. The second widened portion 229B of the power source wiring line 229 overlaps main portions of the TFT 226 (including at least the entire region of a gate electrode 226A and the semiconductor portion 226D). As illustrated in FIG. 13, the first widened portion 229A of the power source wiring line 229 is connected to the upper electrode 225C of the photoelectric conversion element 225 through the sixth contact hole CH6 formed as an opening in a third interlayer insulating film 234, a second flattening film 235, and a fourth interlayer insulating film 236.

As illustrated in FIG. 10, similarly to the first embodiment described above, the first opening 235A in the second flattening film 235 extends along the Y-axis direction and intersects a first electrode portion 226B1 that is a portion, of the source electrode 226B, extending along the X-axis direction. In the third embodiment, since the source electrode 226B does not overlap the photoelectric conversion element 225 over the entire region thereof, the first opening 235A overlapping a portion of the first electrode portion 226B1 does not overlap the photoelectric conversion element 225 over the entire region thereof. Therefore, at the time of laser repair, when laser light is irradiated into the first opening 235A, the laser light is not irradiated onto the photoelectric conversion element 225, but irradiated onto the portion of the first electrode portion 226B1 of the source electrode 226B.

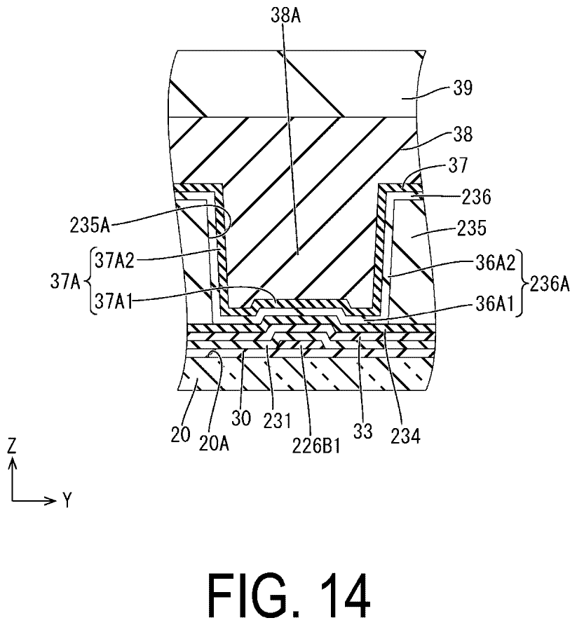

As illustrated in FIGS. 11 and 14, a first covering portion 236A of the fourth interlayer insulating film 236 covers the entire bottom surface and side surface of the opening edge of the first opening 235A having the above-described configuration, from the upper layer side. In the third embodiment also, similarly to the first embodiment, a region inside the first opening 235A in the second flattening film 235, that is, the range irradiated with the laser light can be surrounded by the first covering portion 236A. Therefore, even if moisture or the like enters the region inside the first opening 235A due to the irradiation of the laser light, the moisture or the like can be made less likely to diffuse into the second flattening film 235 due to the first covering portion 236A. In this way, it is possible to make it less likely for the characteristics of the photoelectric conversion elements 225 to deteriorate.

### OTHER EMBODIMENTS

The techniques disclosed herein are not limited to the embodiments described above and illustrated in the drawings, and the following embodiments, for example, are also included within the technical scope.

(1) An object to be irradiated with laser light at the time of laser repair may be a structure other than the source electrodes 26B, 126B, and 226B. For example, the laser light can be irradiated onto the scanning wiring line 27. In this case, the first opening 35A, 135A, 235A may be provided at a position overlapping a portion, of the scanning wiring line 27, irradiated with the laser light. When there is a possibility that the laser light may be irradiated onto either of the source electrode 26B, 126B, 226B and the scanning wiring line 27, the first openings 35A, 135A, 235A can be provided both at a position overlapping a portion of the source electrode 26B, 126B, 226B and at a position overlapping a portion of the scanning wiring line 27. Since the scanning wiring line 27 does not overlap the photoelectric conversion element 25, 125, 225, even if the laser light is irradiated onto a portion of the scanning wiring line 27, a short circuit between the scanning wiring line 27 and the photoelectric conversion element 25, 125, 225 is less likely to occur.

(2) Also in the configuration described in the second embodiment, as described in (1) above, the first opening 135A and the second opening 132A can be provided at positions overlapping the portion, of the scanning wiring line 27, irradiated with laser light, respectively.

(3) In the configuration described in the third embodiment, for example, laser light can be irradiated onto the drain electrode 226C. In this case, the first opening 235A may be provided at a position overlapping a portion, of the drain electrode 226C, irradiated with the laser light. When there is a possibility that the laser light may be irradiated onto either of the source electrode 226B or the drain electrode 226C, the first openings 235A can be provided both at a position overlapping a portion of the source electrode 226B and at a position overlapping a portion of the drain electrode 226C. Since the drain electrode 226C does not overlap the photoelectric conversion element 225, even if the laser light is irradiated onto a portion of the drain electrode 226C, a short circuit between the drain electrode 226C and the photoelectric conversion element 225 is less likely to occur.

(4) Also in the configuration described in the first embodiment, as described in (3) above, the first opening 35A can be provided at a position overlapping the portion, of the drain electrode 26C, irradiated with laser light. In this case, the photoelectric conversion element 25 preferably does not overlap the portion, of the drain electrode 26C, irradiated with the laser light.

(5) Also in the configuration described in the second embodiment, as described in (3) above, the first opening 135A and the second opening 132A can be provided at positions overlapping the portion, of the drain electrode 26C, irradiated with laser light, respectively. In this case, the photoelectric conversion element 125 preferably does not overlap the portion, of the drain electrode 26C, irradiated with the laser light.

(6) Specific materials, numerical values of the film thicknesses, film configurations, and the like used for each of the metal films, each of the insulating films 30 to 38, 131 to 138, 231, 234, 235, and 236, each of the semiconductor films, each of the transparent electrode films, and the like can be changed as appropriate. For example, the gate insulating film 30 may be a single-layer film. The first interlayer insulating films 31 and 131, the second interlayer insulating films 33 and 133, the third interlayer insulating films 34, 134, and 234, the fourth interlayer insulating films 36, 136, and 236, and the fifth interlayer insulating films 37 and 137 may each be a layered film. Even in this case, particularly each of the third interlayer insulating films 34, 134, and 234, the fourth interlayer insulating films 36, 136, and 236, and the fifth interlayer insulating films 37 and 137 preferably includes a film made of SiN in the layered film.

(7) The planar shape of the imaging region IA may be a square, a vertically long rectangle, or the like, and may be changed as appropriate.

(8) The scanning signal control circuit 22 and the signal detection circuit 23 may be provided in the non-imaging region NIA of the substrate 20.

(9) Instead of the radiation irradiation device 11, an irradiation device that irradiates visible light can be used. In this case, the scintillator 39 can be omitted.

(10) The subject 1 may be an animal other than a human, or may be an article (e.g., a suitcase) other than the animal.

(11) The imaging device 12 may include an imaging element other than the photoelectric conversion element 25, 125, 225.

(12) The imaging device 12 may be used in an image capturing system other than the radiographic image capturing system 10.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. An imaging device comprising:
an imaging element;
a first circuit element disposed on a lower layer side of the imaging element;
a first insulating film disposed on an upper layer side of the imaging element;
a second insulating film disposed on an upper layer side of the first insulating film; and
a third insulating film disposed on an upper layer side of the second insulating film,
wherein the first insulating film and the third insulating film each include an inorganic insulating material,
the second insulating film includes an organic insulating material and is provided with a first opening overlapping a portion of the first circuit element, and
the third insulating film includes a first covering portion covering an opening edge of the first opening in the second insulating film.

2. The imaging device according to claim 1, further comprising:
a second circuit element disposed on an upper layer side of the third insulating film; and
a fourth insulating film disposed on an upper layer side of the second circuit element,
wherein the fourth insulating film includes an inorganic insulating material and includes a second covering portion covering the first covering portion.

3. The imaging device according to claim 1, further comprising:
a fifth insulating film disposed on an upper layer side of the third insulating film,
wherein the fifth insulating film includes an organic insulating material and includes a first filling portion filled in the first opening.

4. The imaging device according to claim 1,
wherein the first insulating film and the third insulating film each include silicon nitride as the inorganic insulating material.

5. The imaging device according to claim 1, further comprising:
a switching element disposed on the lower layer side of the imaging element; and
a sixth insulating film disposed on an upper layer side of the switching element and on the lower layer side of the imaging element,
wherein the switching element includes the first circuit element or is connected to the first circuit element,
the sixth insulating film includes an organic insulating material and is provided with a second opening overlapping the first opening, and
the third insulating film includes a third covering portion covering an opening edge of the second opening in the sixth insulating film.

6. The imaging device according to claim 5,
wherein the first insulating film includes a fourth covering portion covering the opening edge of the second opening in the sixth insulating film, and
the third covering portion covers the fourth covering portion.

7. The imaging device according to claim 5, further comprising:
a second circuit element disposed on an upper layer side of the third insulating film; and
a fourth insulating film disposed on an upper layer side of the second circuit element,
wherein the fourth insulating film includes an inorganic insulating material and includes a fifth covering portion covering the third covering portion.

8. The imaging device according to claim 5, further comprising:
a seventh insulating film disposed on an upper layer side of the sixth insulating film,
wherein the seventh insulating film includes an inorganic insulating material and includes a sixth covering portion covering the opening edge of the second opening in the sixth insulating film.

9. The imaging device according to claim 5, further comprising:
a fifth insulating film disposed on an upper layer side of the third insulating film,
wherein the fifth insulating film includes an organic insulating material and includes a first filling portion filled in the first opening and a second filling portion filled in the second opening.

10. The imaging device according to claim 1, further comprising:
a switching element disposed on the lower layer side of the imaging element,
wherein the switching element includes a gate electrode, a semiconductor portion spaced apart from and overlapping the gate electrode, a source electrode connected to the semiconductor portion, and a drain electrode connected to the semiconductor portion at a position spaced apart from the source electrode,
the imaging element does not overlap at least a portion of the source electrode and overlaps the gate electrode, the semiconductor portion, and the drain electrode, and
the first circuit element is the source electrode.
